(19) United States
(12) Patent Application Publication
(10) Pub. No.: US 2026/0033329 A1
(43) Pub. Date: Jan. 29, 2026

(54) ELECTRONIC DEVICE AND MANUFACTURING METHOD FOR ELECTRONIC DEVICE

(71) Applicant: NEC Platforms, Ltd., Kawasaki-shi, Kanagawa (JP)

(72) Inventor: Yasuhito NAKAMURA, Kanagawa (JP)

(73) Assignee: NEC Platforms, Ltd., Kawasaki-shi, Kanagawa (JP)

(21) Appl. No.: 18/996,120

(22) PCT Filed: Sep. 7, 2023
(86) PCT No.: PCT/JP2023/032617

§ 371 Date: Jan. 17, 2025

(30) Foreign Application Priority Data
Sep. 9, 2022 (JP) 2022-143422

(51) Int. Cl. H01L 23/367; H01L 23/00; H01L 23/40; H01L 23/433

(52) U.S. Cl. CPC H01L 23/3675; H01L 23/433; H01L 24/16; H01L 24/32; H01L 24/73; H01L 24/83; H01L 23/4006; H01L 2224/16225; H01L 2224/32225; H01L 2224/73253; H01L 2224/83191; H01L 2224/83201

(57) ABSTRACT

An electronic device according to the present invention includes: a semiconductor chip that is mounted on a substrate; a heat sink that is attached to the substrate so as to face the upper surface of the semiconductor chip; a liquid metal that comes into contact with the upper surface of the semiconductor chip and the lower surface of the heat sink; seal members that are provided so as to surround the liquid metal and that seal an area between the upper surface of the substrate and the lower surface of the heat sink; and communication sections that are provided in the heat sink and communicate the internal space surrounded by the seal members, the semiconductor ship, and the heat sink, with the outside of the heat sink.

### TECHNICAL FIELD

The present disclosure relates to an electronic device and a manufacturing method for the electronic device.

### BACKGROUND ART

A semiconductor chip such as a processor or an image processing integrated circuit (IC) generates heat with operation. A heat sink is used to dissipate this heat. The heat sink is attached to, for example, an upper surface of the semiconductor chip. At this time, a thermally conductive substance may be interposed between the semiconductor chip and the heat sink in order to improve thermal conduction. The thermally conductive substance is also referred to as a thermal interface material (TIM).

In recent years, an amount of heat generated by the semiconductor chip has increased with an increase in performance. Therefore, it has been proposed to use a liquid metal having high thermal conductivity as the TIM. For example, PTL 1 discloses an invention of an electronic device or the like in which a thermally conductive material is provided between a semiconductor chip and a heat sink (radiator). In the electronic device of PTL 1, a conductor element on a substrate is covered with an insulating portion. The thermally conductive material is surrounded by a seal member provided on the insulating portion. The thermally conductive material has conductivity. The thermally conductive material has fluidity at least at a time of operation of the semiconductor chip to generate heat. PTL 1 exemplifies a configuration using a liquid metal as the thermally conductive material. The liquid metal is a metal that is liquid at room temperature. In this configuration, a range over which the thermally conductive material spreads is limited by the seal member. Here, parts and circuits that need to be avoided from contact with the liquid metal are disposed outside the seal member. Alternatively, the parts and the circuits are disposed below the insulating portion. A problem of the above is, for example, a short circuit. With such a configuration, occurrence of the problem such as the short circuit caused by spreading of the liquid metal (thermally conductive material) is suppressed.

PTL 2 also discloses a related technology.

### CITATION LIST

### Patent Literature

PTL 1: WO 2020/162417 A1
PTL 2: WO 2005/024940 A1

### SUMMARY OF INVENTION

### Technical Problem

In the technology of PTL 1, a region surrounded by the insulating portion, the heat sink, and the seal member is a sealed space. Therefore, when temperature of the semiconductor chip rises, pressure of gas in the sealed space rises. This pressure acts on a semiconductor device as force in a direction to separate the heat sink from the seal member. Therefore, there is a risk that a seal structure including the heat sink, the seal member, and the insulating portion may be damaged.

The present invention has been made in view of the above problems, and an object of the present invention is to provide an electronic device or the like in which a seal structure is less likely to be damaged when temperature rises.

### Solution to Problem

In order to solve the above problems, an electronic device of the present invention includes a semiconductor chip mounted on a substrate, a heat sink attached to the substrate in such a way as to face an upper surface of the semiconductor chip, a liquid metal in contact with the upper surface of the semiconductor chip and a lower surface of the heat sink, a seal member that is provided in such a way as to surround the liquid metal when viewed in a direction perpendicular to a surface of the substrate and seals between an upper surface of the substrate and the lower surface of the heat sink, and a communication portion that is provided in the heat sink and communicates a first internal space surrounded by the seal member, the semiconductor chip, and the heat sink with an outside of the heat sink.

A manufacturing method for an electronic device of the present invention includes supplying a liquid metal to an upper surface of a semiconductor chip mounted on a substrate, attaching a seal member in such a way as to surround the liquid metal, attaching a heat sink in such a way that a lower surface of the heat sink is in contact with the liquid metal, the heat sink including a communication portion that communicates an internal space between the seal member and the semiconductor chip with an outside of the heat sink, and fixing the heat sink to the substrate.

### Advantageous Effects of Invention

An effect of the present invention is that an electronic device or the like in which a seal structure is less likely to be damaged when temperature rises can be provided.

### BRIEF DESCRIPTION OF DRAWINGS

FIG. 1 is a schematic cross-sectional view illustrating an electronic device of a first example embodiment.

FIG. 2 is a schematic plan view illustrating the electronic device of the first example embodiment.

FIG. 3 is a schematic cross-sectional view illustrating a first state of a manufacturing method for the electronic device of the first example embodiment.

FIG. 4 is a schematic cross-sectional view illustrating a second state of the manufacturing method for the electronic device of the first example embodiment.

FIG. 5 is a schematic cross-sectional view illustrating a third state of the manufacturing method for the electronic device of the first example embodiment.

FIG. 6 is a schematic cross-sectional view illustrating a fourth state of the manufacturing method for the electronic device of the first example embodiment.

FIG. 7 is a schematic cross-sectional view illustrating a modification of the electronic device of the first example embodiment.

FIG. 8 is a schematic cross-sectional view illustrating an electronic device of a second example embodiment.

FIG. 9 is a schematic cross-sectional view illustrating a first modification of the electronic device of the second example embodiment.

FIG. 10 is a schematic cross-sectional view illustrating a second modification of the electronic device of the second example embodiment.

FIG. 11 is a schematic cross-sectional view illustrating a third modification of the electronic device of the second example embodiment.

FIG. 12 is a schematic cross-sectional view illustrating a fourth modification of the electronic device of the second example embodiment.

### EXAMPLE EMBODIMENT

Hereinafter, example embodiments of the present invention will be described in detail with reference to the drawings. Note that the example embodiments described below have technically preferable limitations for carrying out the present invention, but the scope of the invention is not limited to the following. Similar components in the drawings are denoted by the same numerals, and description of these components may be omitted.

### First Example Embodiment

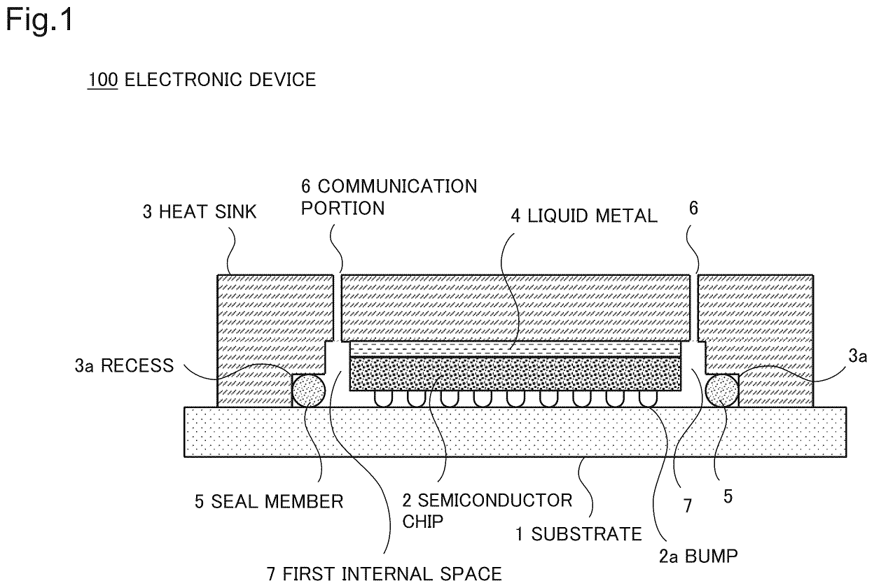

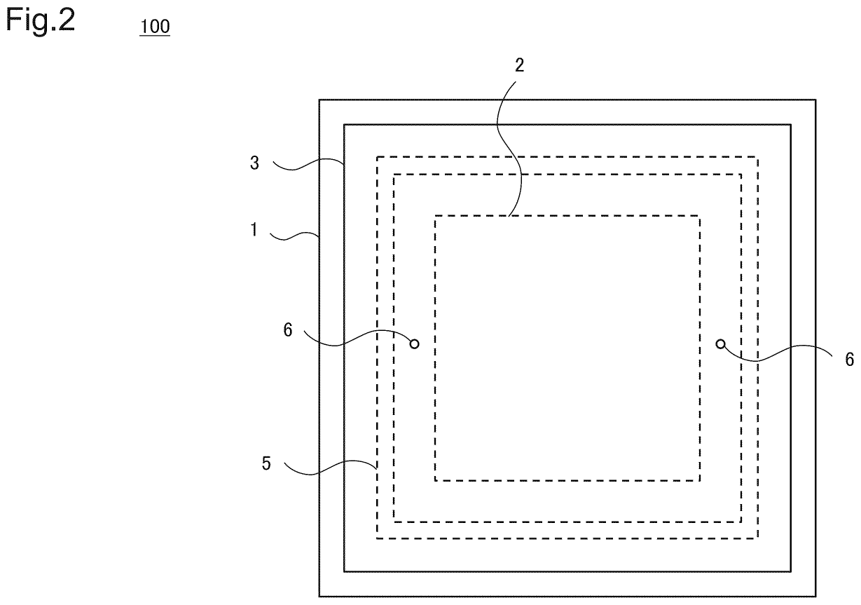

FIG. 1 is a schematic cross-sectional view illustrating an electronic device 100 of a first example embodiment of the present invention. FIG. 2 is a schematic plan view illustrating the electronic device 100 of the first example embodiment. The electronic device 100 includes a substrate 1, a semiconductor chip 2, a heat sink 3, a liquid metal 4, and a seal member 5.

The substrate 1 is obtained by, for example, forming wiring on a surface of an insulating base. A material of the base is, for example, a heat-resistant plastic such as ceramic, glass epoxy, or polyimide.

The semiconductor chip 2 is mounted on the substrate 1. The semiconductor chip 2 is, for example, a central processing unit (CPU) or a graphics processing unit (GPU). The semiconductor chip 2 is connected to the wiring of the substrate 1 by, for example, bumps 2a. The bump 2a may be, for example, a solder ball.

The heat sink 3 is attached to the substrate 1 in such a way as to face an upper surface of the semiconductor chip 2. The heat sink 3 is formed of, for example, a metal having high thermal conductivity. Specifically, for example, copper, aluminum, or the like is used as a material of the heat sink 3. Note that, in a case where the liquid metal 4 reacts with aluminum, for example, copper is used. The heat sink 3 is fixed to the substrate 1. For example, the heat sink 3 is fixed to the substrate 1 using an adhesive.

The liquid metal 4 is provided in such a way as to be in contact with the upper surface of the semiconductor chip 2 and a lower surface of the heat sink 3. The liquid metal is a metal that is liquid at room temperature (for example, 25° C.). As a material of the liquid metal, for example, an alloy including gallium, indium, tin, or the like is used. Thermal conduction from the semiconductor chip 2 to the heat sink 3 is supported by the liquid metal 4.

The seal member 5 is provided in such a way as to surround the liquid metal 4. More specifically, the seal member 5 is provided in such a way as to surround the semiconductor chip 2 and the liquid metal 4 when viewed in a direction perpendicular to a surface of the substrate 1. The seal member 5 seals between an upper surface of the substrate 1 and the lower surface of the heat sink 3. A shape of the seal member 5 is determined according to, for example, a planar shape of the semiconductor chip 2. For example, when the semiconductor chip 2 is rectangular, the seal member 5 has a rectangular ring shape. The seal member 5 is compressed when the heat sink 3 is attached to the substrate 1. As a result, it is possible to suppress generation of a gap on a bonding surface between the upper surface of the substrate 1 and a lower surface of the semiconductor chip 2.

A first internal space 7 surrounded by the substrate 1, the seal member 5, the semiconductor chip 2, and the heat sink 3 is formed inside the heat sink 3. The heat sink 3 is provided with a communication portion 6 that communicates the first internal space 7 with the outside of the heat sink 3. At least one communication portion 6 is provided. In the example of FIG. 2, two communication portions 6 are provided. When a plurality of the communication portions 6 is provided, gas can flow through the remaining communication portions 6 even when a part of the communication portions 6 is closed. That is, providing the plurality of communication portions 6 increases redundancy.

The communication portion 6 is, for example, a through hole extending from an upper surface to the lower surface of the heat sink 3. The communication portion 6 allows gas to flow between the first internal space 7 and an outer surface of the heat sink 3. In a case where the communication portion 6 is a through hole, a diameter of the through hole is set to a range of 0.01 mm to 3 mm, for example. In order to prevent foreign matter from entering from the outside, the diameter is preferably small. However, when the diameter is too small, the through hole is easily closed. Therefore, the diameter is set to equal to or more than 0.01 mm. When the diameter is 2 mm to 3 mm, even when the liquid metal 4 enters the through hole, the liquid metal 4 easily comes out of the through hole.

In the electronic device 100, temperature of gas in the first internal space 7 also rises due to rise in temperature of the semiconductor chip 2. In the above configuration, since gas can flow through the communication portion 6, rise in air pressure of the first internal space 7 is suppressed. Therefore, a seal structure using the seal member 5 is less likely to be damaged. On the other hand, when the internal space is sealed as in PTL 1, stress is generated in the seal member, an adhesive portion of the seal member, and the like due to rise in pressure. Therefore, the seal structure is easily damaged.

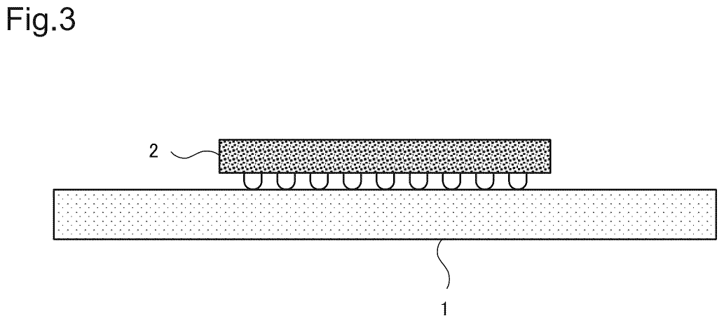

Next, a manufacturing method for the electronic device 100 will be described. FIG. 3 is a schematic cross-sectional view illustrating a first state of the manufacturing method for the electronic device 100 of the first example embodiment. The substrate 1 on which the semiconductor chip 2 is mounted as illustrated in FIG. 3 is a starting point.

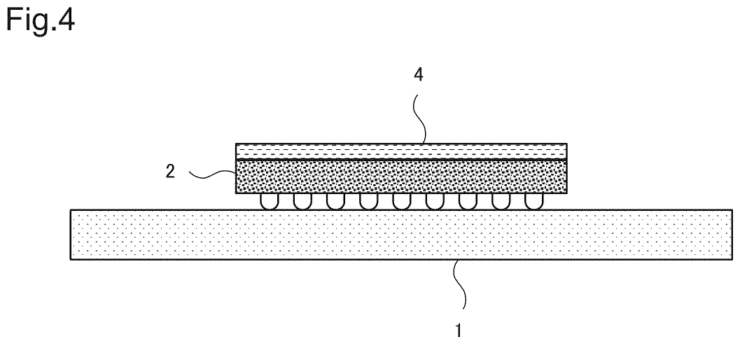

FIG. 4 is a schematic cross-sectional view illustrating a second state of the manufacturing method for the electronic device 100 of the first example embodiment. As illustrated in FIG. 4, the liquid metal 4 is applied to the upper surface of the semiconductor chip 2. At this time, equal to or less than a predetermined thickness of the liquid metal 4 is applied in such a way that the excess liquid metal does not go out of the upper surface of the semiconductor chip 2.

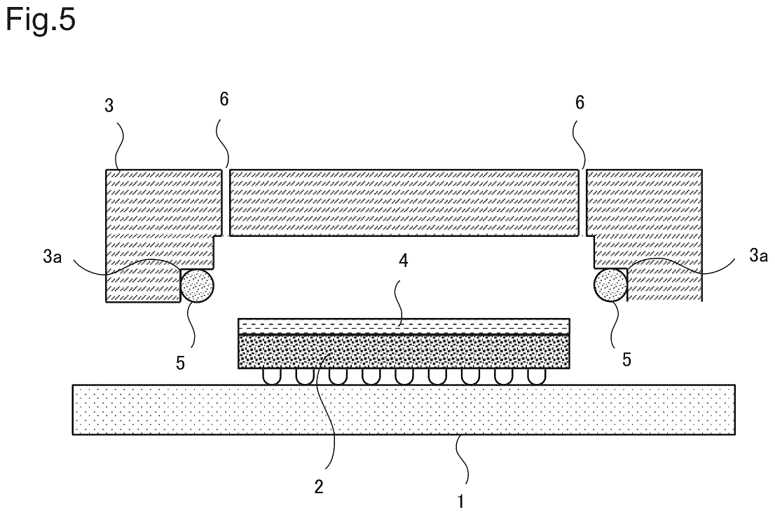

FIG. 5 is a schematic cross-sectional view illustrating a third state of the manufacturing method for the electronic device 100 of the first example embodiment. As illustrated in FIG. 5, the seal member 5 is attached to a recess 3a of the heat sink 3. Although not illustrated, wiring or an insulating layer may be formed on the upper surface of the substrate 1.

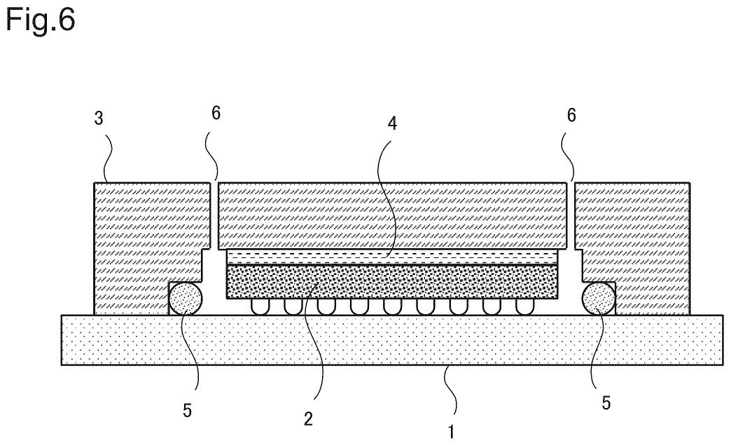

FIG. 6 is a schematic cross-sectional view illustrating a fourth state of the manufacturing method for the electronic device 100 of the first example embodiment. As illustrated in FIG. 6, the heat sink 3 is attached to the substrate 1 in such a way that the lower surface of the heat sink 3 is in contact with the liquid metal 4. Although not illustrated, the heat sink 3 is fixed to the substrate 1 by an adhesive layer or the like. At this time, the heat sink 3 and the substrate 1 sandwich the seal member 5, in such a way that the heat sink 3 and the substrate 1 are sealed. The first internal space 7 surrounded by the semiconductor chip 2, the substrate 1, the seal member 5, and the heat sink 3 are formed. The communication portion 6 provided in the heat sink 3 allows gas to flow between the first internal space 7 and the outer surface of the heat sink 3.

### Modification

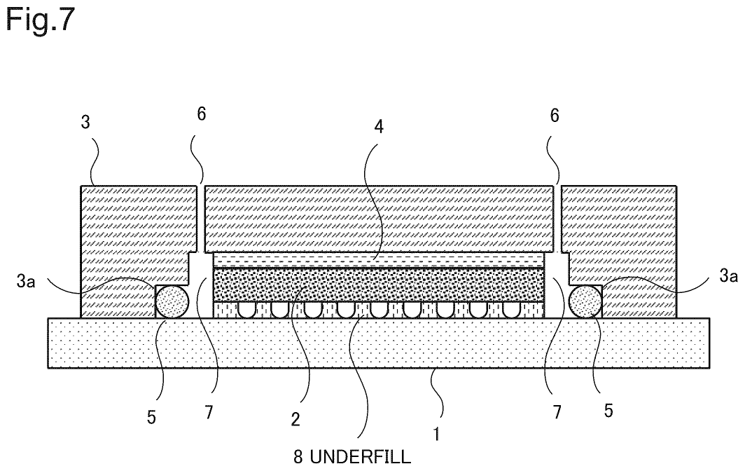

FIG. 7 is a schematic cross-sectional view illustrating a modification of the electronic device 100 of the first example embodiment. In this modification, a gap between the bumps 2a connecting the substrate 1 and the semiconductor chip 2 is filled with an insulating underfill 8. When fluidity of the liquid metal 4 is increased by temperature rise, the liquid metal 4 may be spilled from the upper surface of the semiconductor chip 2 onto the substrate 1. Presence of the underfill 8 can prevent a short circuit between the bumps 2a due to the liquid metal 4 in such a case.

The electronic device 100 and the like of the present example embodiment have been described above.

The electronic device 100 of the present example embodiment includes the semiconductor chip 2, the heat sink 3, the liquid metal 4, and the seal member 5 mounted on the substrate 1. The heat sink 3 is attached to the substrate 1 in such a way as to face the upper surface of the semiconductor chip 2. The liquid metal 4 is provided in such a way as to be in contact with the upper surface of the semiconductor chip 2 and the lower surface of the heat sink 3. The seal member 5 is provided in such a way as to surround the liquid metal 4 when viewed in the direction perpendicular to the surface of the substrate. The seal member 5 seals between the upper surface of the substrate 1 and the lower surface of the heat sink 3. The heat sink 3 is provided with the communication portion 6. The first internal space 7 surrounded by the seal member 5, the semiconductor chip 2, and the heat sink 3 is formed inside the heat sink 3. The communication portion 6 communicates the first internal space 7 with the outside of the heat sink 3.

In the above configuration, the communication portion 6 allows the first internal space 7 to communicate with the outside of the heat sink 3. Therefore, when the temperature of the semiconductor chip 2 rises and air temperature of the first internal space 7 rises, rise in the air pressure in the first internal space 7 is suppressed. Therefore, the seal structure including the seal member is less likely to be damaged as compared with the configuration in which the internal space is sealed.

According to an aspect, the heat sink 3 of the electronic device 100 has the recess 3a that accommodates the seal member 5. The communication portion 6 communicates the recess 3a with the outside of the heat sink 3.

A space for retracting an increase in volume when the liquid metal 4 is expanded is secured by the recess 3a.

According to an aspect, in the electronic device 100, the communication portion 6 includes at least one through hole that connects the first internal space 7 and the outer surface of the heat sink 3. The through hole allows gas to flow. By providing the plurality of through holes, even when a part of the through holes is closed, the first internal space 7 and the outside of the heat sink 3 communicate with each other by the remaining through holes.

According to an aspect, in the electronic device 100, the diameter of the through hole is in the range of 0.01 mm to 3 mm.

When the diameter of the through hole is within the above range, foreign matter is less likely to enter from the through hole. When the diameter is 2 mm to 3 mm, even when the liquid metal 4 enters the through hole, the liquid metal 4 easily comes out of the through hole. This is because liquid level rise due to a capillary phenomenon is small.

In the manufacturing method for the electronic device 100 according to the present example embodiment, the liquid metal 4 is supplied to the upper surface of the semiconductor chip 2 mounted on the substrate 1. The seal member 5 is attached in such a way as to surround the liquid metal 4. The heat sink 3 is attached in such a way that the lower surface is in contact with the liquid metal 4. The heat sink 3 includes the communication portion 6 that communicates the first internal space 7 with the outside of the heat sink 3. Here, the first internal space 7 is a space between the seal member 5 and the semiconductor chip 2. The heat sink 3 is fixed to the substrate 1.

By such a manufacturing method, the electronic device 100 having good thermal conduction from the semiconductor chip 2 to the heat sink 3 and the seal structure that is less likely to be damaged is easily manufactured.

### Second Example Embodiment

In the electronic device 100 of the first example embodiment, the seal member 5 is in direct contact with the substrate 1 to seal between the heat sink 3 and the substrate 1. However, a configuration in which the heat sink 3 and the substrate 1 are sealed via the semiconductor chip 2 is also possible. Such a configuration will be described in the present example embodiment.

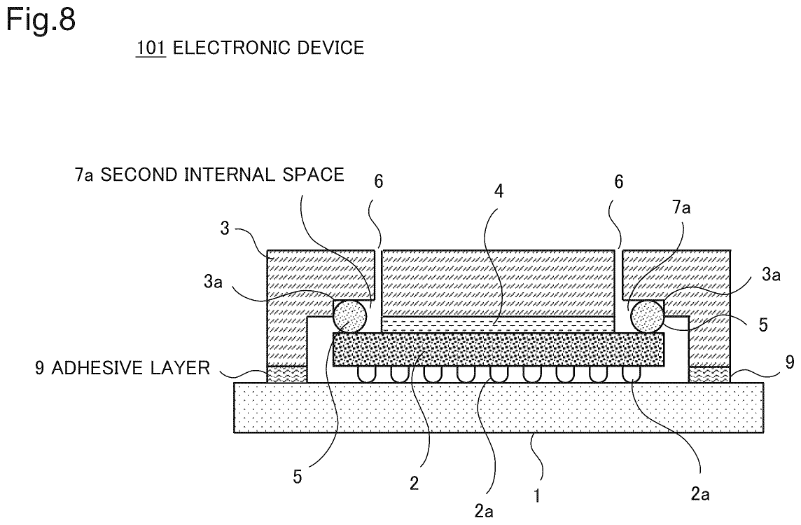

FIG. 8 is a schematic cross-sectional view illustrating an electronic device 101 of a second example embodiment. Similarly to the electronic device 100 of the first example embodiment, the electronic device 100 includes a substrate 1, a semiconductor chip 2, a heat sink 3, a liquid metal 4, and a seal member 5. A difference is that the seal member 5 is attached to an upper surface of the semiconductor chip 2.

The semiconductor chip 2 is mounted on the substrate 1. The heat sink 3 is attached to the substrate 1 in such a way as to face the upper surface of the semiconductor chip 2.

The liquid metal 4 is applied to the upper surface of the semiconductor chip 2. Here, for example, an inner side by a first distance from ends of the semiconductor chip 2 is set to an application range of the liquid metal 4.

On the upper surface of the semiconductor chip 2, the seal member 5 is provided in such a way as to surround the liquid metal 4 when viewed in a direction perpendicular to a surface of the substrate. More specifically, the seal member 5 is provided on the upper surface of the semiconductor chip 2 in such a way as to surround the liquid metal 4 when viewed in the direction perpendicular to the surface of the substrate 1. Here, for example, a gap having a second distance is formed between ends of the liquid metal 4 and the seal member 5. However, even when there is no gap, there is no particular problem in operation of the electronic device 101.

The heat sink 3 includes a recess 3a for accommodating the seal member 5. The recess 3a provides a second internal space 7a for retracting an increase in volume when the liquid metal 4 expands. Therefore, a capacity of the second internal space 7a is set to be equal to or more than the volume that increases when the liquid metal 4 thermally expands. When operation temperature of the semiconductor chip 2 is about 200° C. at the maximum, for example, 10 to 100% of the volume of the liquid metal 4 is set as the capacity of the second internal space 7a.

Then, the heat sink 3 is attached to the substrate 1 in such a way that a lower surface of the heat sink 3 is in contact with an upper surface of the liquid metal 4. The heat sink 3 is fixed to the substrate 1. In the example of FIG. 8, the heat sink 3 is fixed to the substrate 1 by an adhesive layer 9.

In the above configuration, the seal member 5 seals between the upper surface of the semiconductor chip 2 and the lower surface of the heat sink 3. A shape of the seal member 5 is determined according to, for example, a planar shape of the semiconductor chip 2. For example, when the semiconductor chip 2 is rectangular, the seal member 5 has a rectangular ring shape.

The second internal space 7a surrounded by the seal member 5, the semiconductor chip 2, and the heat sink 3 is formed inside the heat sink 3 related to the recess 3a of the heat sink 3. The heat sink 3 is provided with a communication portion 6 that communicates the second internal space 7a with the outside of the heat sink 3. At least one communication portion 6 is provided. In the example of FIG. 8, two communication portions 6 are provided.

In the above configuration, the seal member 5 is attached to the upper surface of the semiconductor chip 2, and the seal member 5 surrounds the liquid metal 4. Therefore, even when the liquid metal 4 spreads toward the ends of the semiconductor chip 2 due to temperature rise or the like, the liquid metal 4 does not flow out onto the substrate 1. When there is a circuit on the substrate 1 and the liquid metal 4 flows into the circuit, a defect such as a short circuit may occur. However, in the configuration of FIG. 8, the liquid metal 4 does not spread out of the seal member 5. Therefore, such a defect does not occur in the electronic device 101.

### First Modification

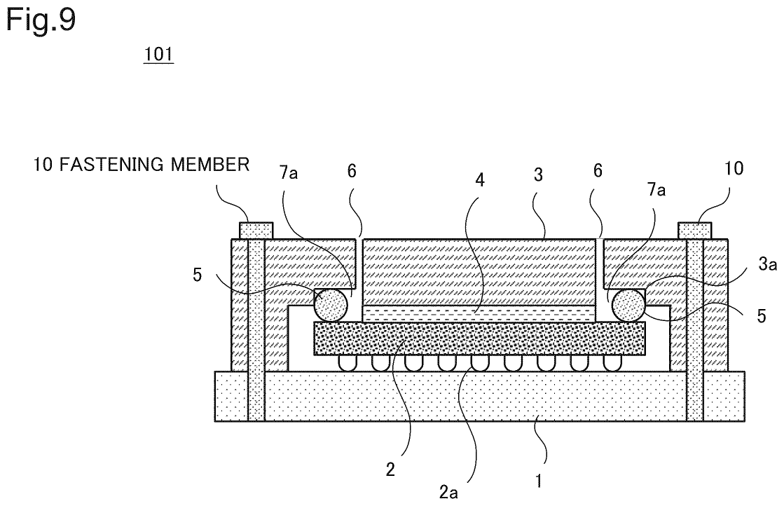

FIG. 9 is a schematic cross-sectional view illustrating a first modification of the electronic device 101 of the second example embodiment. In the first modification, the heat sink 3 is fixed to the substrate 1 by using a fastening member 10. A compression amount of the seal member 5 is adjusted by adjusting fastening force of the fastening member 10.

### Second Modification

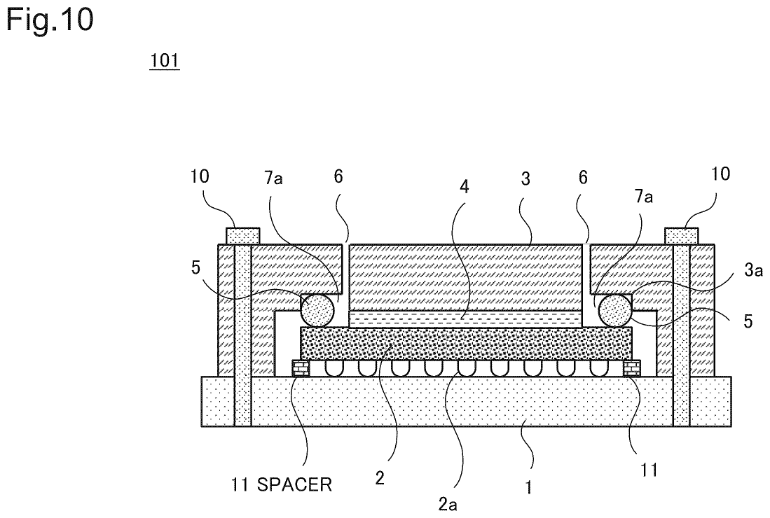

FIG. 10 is a schematic cross-sectional view illustrating a second modification of the electronic device 101 of the second example embodiment. In the electronic device 101 of the second modification, spacers 11 are provided at ends of a lower surface of the semiconductor chip 2. The spacer 11 is formed of a material that is hardly deformed, for example, ceramic or glass. With the presence of the spacer 11, an interval between the semiconductor chip 2 and the substrate 1 is maintained at a distance related to a thickness of the spacer 11. Therefore, deformation of bumps 2a when the fastening member 10 is fastened is prevented.

### Third Modification

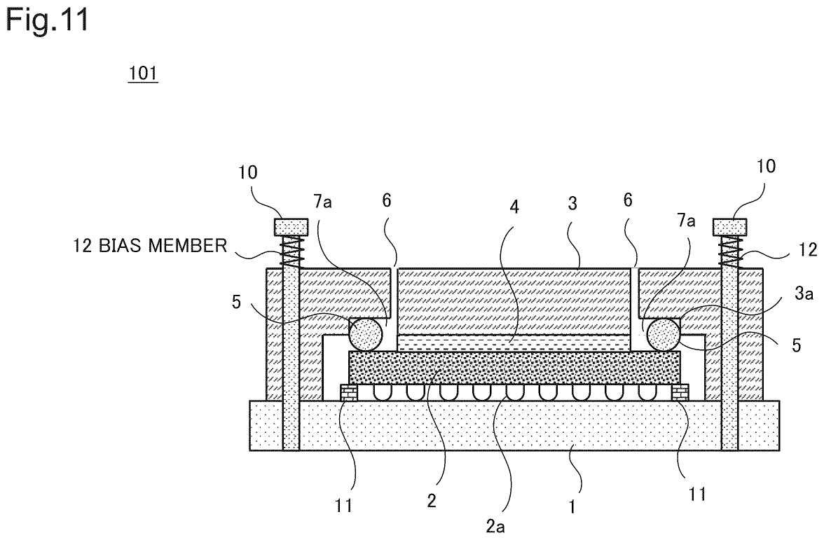

FIG. 11 is a schematic cross-sectional view illustrating a third modification of the electronic device 101 of the second example embodiment. In the third modification, a bias member 12 is attached to an upper surface side of the heat sink 3 of the fastening member 10. The presence of the bias member 12 prevents excessive fastening of the fastening member 10. This makes adjustment of the compression amount of the seal member 5 easy.

### Fourth Modification

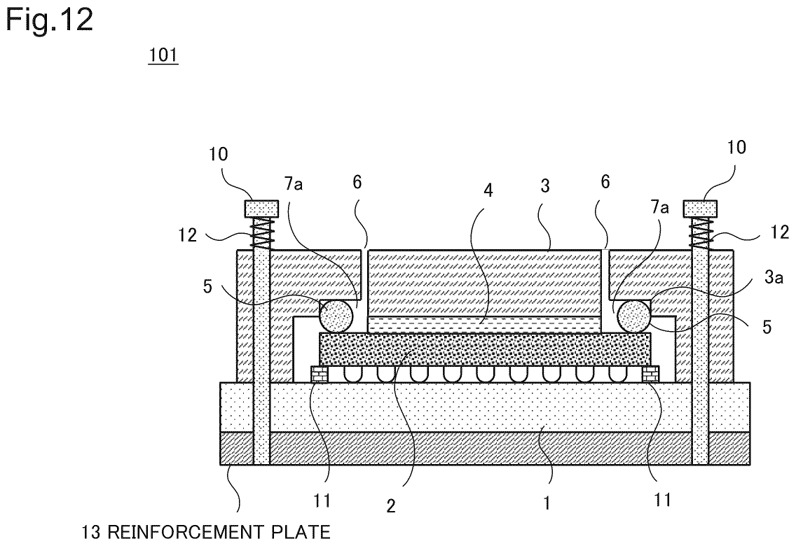

FIG. 12 is a schematic cross-sectional view illustrating a fourth modification of the electronic device 101 of the second example embodiment. In the electronic device 101 of the fourth modification, a reinforcement plate 13 is attached to a lower surface of the substrate 1. The reinforcement plate 13 is fixed to the substrate 1 by the fastening member 10. For example, in a case where the substrate 1 is ceramic, it is not easy to form a screw hole. At this time, for example, by using a material that is easy to process, such as a metal plate, it is easy to form the screw hole. The reinforcement plate 13 enhances mechanical strength of the electronic device 100.

The electronic device 101 and the like of the present example embodiment have been described above.

The electronic device 101 of the present example embodiment includes the semiconductor chip 2, the heat sink 3, the liquid metal 4, and the seal member 5 mounted on the substrate 1. The heat sink 3 is attached to the substrate 1 in such a way as to face the upper surface of the semiconductor chip 2. The liquid metal 4 is provided in such a way as to be in contact with the upper surface of the semiconductor chip 2 and the lower surface of the heat sink 3. The seal member 5 is provided on the upper surface of the semiconductor chip 2. The seal member 5 seals between an upper surface of the substrate 1 and the lower surface of the heat sink 3 via the semiconductor chip 2. The seal member 5 is provided in such a way as to surround the liquid metal 4 when viewed in the direction perpendicular to the surface of the substrate 1. The heat sink 3 is provided with the communication portion 6. The second internal space 7a surrounded by the seal member 5, the semiconductor chip 2, and the heat sink 3 is formed inside the heat sink 3. The communication portion 6 communicates the second internal space 7a with the outside of the heat sink 3.

In the above configuration, the communication portion 6 allows the second internal space 7a to communicate with the outside of the heat sink 3. Therefore, when temperature of the semiconductor chip 2 rises and air temperature of the second internal space 7a rises, rise in air pressure in the second internal space 7a is suppressed. Therefore, a seal structure including the seal member 5 is less likely to be damaged as compared with the configuration in which the internal space is sealed. The seal member 5 is attached to the upper surface of the semiconductor chip 2, and the seal member 5 surrounds the liquid metal 4. Therefore, even when the liquid metal 4 spreads toward the ends of the semiconductor chip 2 due to temperature rise or the like, the liquid metal 4 does not flow out onto the substrate 1.

According to an aspect, in the electronic device 101, the heat sink 3 is fixed to the substrate 1 by the fastening member 10.

In this configuration, the compression amount of the seal member 5 is adjusted by adjusting the fastening force of the fastening member 10.

According to an aspect, the electronic device 101 includes the spacers 11 for maintaining the interval between the semiconductor chip 2 and the substrate 1 at the first distance.

The spacers 11 prevent damage to the bumps 2a due to fastening.

According to an aspect, the electronic device 101 includes the bias member 12 that biases the fastening member 10 above the heat sink 3.

The biasing of the bias member 12 makes adjustment of the fastening force of the fastening member 10 easy.

According to an aspect, the electronic device 101 includes the reinforcement plate 13 that is provided on a back surface side of the substrate 1 and reinforces the substrate 1.

Strength of the substrate 1 is reinforced by the reinforcement plate 13.

The present invention has been described above by using the above-described example embodiments as model examples. However, the present invention is not limited to the above-described example embodiments. That is, the present invention can apply various aspects that will be understood by those of ordinary skill in the art within the scope of the present invention.

This application is based upon and claims the benefit of priority from Japanese patent application No. 2022-143422, filed on Sep. 9, 2022, the disclosure of which is incorporated herein in its entirety by reference.

### REFERENCE SIGNS LIST

1 substrate
2 semiconductor chip
2a bump
3 heat sink
4 liquid metal
5 seal member
6 communication portion
7 first internal space
8 underfill
9 adhesive layer
10 fastening member
11 spacer
12 bias member
13 reinforcement plate
100, 101 electronic device

What is claimed is:

1. An electronic device comprising:
a semiconductor chip mounted on a substrate;
a heat sink attached to the substrate, the heat sink facing an upper surface of the semiconductor chip;
a liquid metal disposed between and in contact with the upper surface of the semiconductor chip and a lower surface of the heat sink;
a seal member that is configured to surround the liquid metal when viewed in a direction perpendicular to a surface of the substrate and provides a seal between an upper surface of the substrate and the lower surface of the heat sink; and
a communication portion that is provided in the heat sink, wherein the communication portion connects a first internal space to an outside of the heat sink, the first internal space being surrounded by the substrate, the seal member, the semiconductor chip, and the heat sink.

2. The electronic device according to claim 1, wherein
the seal member is provided on the upper surface of the semiconductor chip to surround the liquid metal when viewed in the direction perpendicular to the surface of the substrate, and provides a seal between the upper surface of the semiconductor chip and the lower surface of the heat sink, and
the communication portion connects a second internal space to the outside of the heat sink, the second internal space being surrounded by the seal member, the semiconductor chip, and the heat sink.

3. The electronic device according to claim 1, wherein
the heat sink
includes a recess that accommodates the seal member, and
the communication portion connects the recess to the outside of the heat sink.

4. The electronic device according to claim 1, wherein
the communication portion
includes at least one through hole that connects the first internal space to an outer surface of the heat sink.

5. The electronic device according to claim 4, wherein
a diameter of the through hole is in a range of 0.01 mm to 3 mm.

6. The electronic device according to claim 1, wherein
the heat sink is
fixed to the substrate by a fastening member.

7. The electronic device according to claim 6, further comprising
a spacer for maintaining an interval between the semiconductor chip and the substrate at a first distance.

8. The electronic device according to claim 6, further comprising
a bias member that biases the fastening member above the heat sink.

9. The electronic device according to claim 6, further comprising
a reinforcement plate that is provided on a back surface side of the substrate and reinforces the substrate.

10. The electronic device according to claim 1, wherein
the liquid metal is
liquid at 25° C.

11. The electronic device according to claim 1, wherein
the heat sink is
fixed to the substrate by an adhesive.

12. A manufacturing method for an electronic device, the method comprising:
supplying a liquid metal to an upper surface of a semiconductor chip mounted on a substrate;
attaching a seal member in such a way as to surround the liquid metal;
attaching a heat sink in such a way that a lower surface of the heat sink is in contact with the liquid metal,
the heat sink including a communication portion that communicates an internal space between the seal member and the semiconductor chip with an outside of the heat sink; and
fixing the heat sink to the substrate.

13. The manufacturing method for an electronic device according to claim 12, wherein
the heat sink is fixed to the substrate
by using a fastening member.

14. The manufacturing method for an electronic device according to claim 13, wherein
spacers for maintaining an interval between the semiconductor chip and the substrate are disposed at ends of the semiconductor chip.
